(19) United States
(12) Patent Application Publication
(10) Pub. No.: US 2026/0324476 A1
(43) Pub. Date: Oct. 15, 2026

(54) SEMICONDUCTOR DEVICE

(71) Applicant: FUJI ELECTRIC CO., LTD., Kawasaki-shi (JP)

(72) Inventor: Tatsuo NISHIZAWA, Matsumoto-city (JP)

(73) Assignee: FUJI ELECTRIC CO., LTD., Kawasaki-shi (JP)

(21) Appl. No.: 19/693,844

(22) Filed: Jun. 1, 2026

Related U.S. Application Data
(63) Continuation of application No. PCT/JP2025/017252, filed on May 12, 2025.

(30) Foreign Application Priority Data
Jun. 14, 2024 (JP) 2024-096828

(51) Int. Cl. H10W 70/66

(52) U.S. Cl. CPC H10W 70/66

(57) ABSTRACT

A semiconductor device includes a semiconductor chip including a lower main electrode on a lower side, an insulated circuit board including an insulating substrate and an upper conductor layer disposed on an upper surface of the insulating substrate, and a bonding layer that bonds the lower main electrode of the semiconductor chip to the upper conductor layer, in which the bonding layer includes a solder material containing tin, a filler containing a first metal having a higher melting point than the solder material and disposed in the solder material, and an alloy layer consisting of an alloy of tin contained in the solder material and the first metal and provided on a surface of the filler, and the alloy layer connects the lower main electrode and the upper conductor layer.

### CROSS-REFERENCE TO RELATED APPLICATION

This application is a Continuation of PCT Application No. PCT/JP2025/017252, filed on May 12, 2025, and claims the priority of Japanese Patent Application No. 2024-096828, filed on Jun. 14, 2024, the content of which are incorporated herein by reference.

### TECHNICAL FIELD

The present disclosure relates to a semiconductor device (semiconductor module) including a power semiconductor chip.

### BACKGROUND ART

A semiconductor device including a power semiconductor chip (hereinafter, simply referred to as a “semiconductor chip”) is, for example, mainly used for a variable-speed drive application and a power conversion application, such as a motor or an inverter. Examples of a bonding material for bonding the semiconductor chip to an insulated circuit board include a solder material and a sintering material. An advantage of using the solder material as the bonding material is that the price is lower than the price of the sintering material.

JP2006-073554A describes that a semiconductor element is bonded to a surface of a land-shaped conductive pattern via solder, metal powder is mixed into the solder in a region corresponding to a corner portion of the semiconductor element, and thus a thickness T1 of the solder is formed to be about 100 μm or more due to the mixed metal powder.

WO2021/065736A1 describes that a collector electrode of a semiconductor device and a heat sink disposed on a back surface side of a semiconductor element are connected via solder, a plurality of wire pieces are provided in a solder bonding portion, all the wire pieces are bonded to a mounting surface of the heat sink and protrude toward the semiconductor element, at least, four or more wire pieces are disposed corresponding to each of four corner portions of the semiconductor element in an outer peripheral region of the solder, and at least one of the wire pieces extends toward an element center in plan view.

WO2022/091988A1 describes that, regarding a bonding structure to be formed when a Si semiconductor or the like and a substrate are used as bonding-target materials and a pair of the bonding-target materials are bonded by liquid-phase diffusion bonding, when an arbitrary cross section of a bonding portion is observed, a characteristic material structure consisting of an island-shaped Ag phase containing 95% by mass or more of Ag and an Ag₃Sn phase consisting of an Ag₃Sn intermetallic compound surrounding the island-shaped Ag phase is exhibited.

JP2014-131076A describes a semiconductor element including a first substrate, a bonding layer provided on one main surface of the first substrate, and a semiconductor mounting component provided on the bonding layer and including a second substrate, a wiring portion provided on the second substrate, and at least one semiconductor chip mounted on the wiring portion, in which a bonding material of the bonding layer contains material particles for forming the bonding layer by being sintered, the material particles include particles having a nanoscale or micron-order size and spacer particles having a size for controlling a thickness of the bonding layer, and the spacer particles include a coating for reaction control on particle surfaces thereof.

WO2021/045131A1 describes a solder paste containing powder of a lead-free solder alloy containing Sn as a main component and metal particles having a higher melting point than the lead-free solder alloy, and describes that the metal particles are formed of a Cu—Ni alloy having a Ni content of 0.1 to 90% by mass or a Cu—Co alloy having a Co content of 0.1 to 90% by mass.

JP2013-138169A describes that, during bonding of printed circuit boards to each other, electrodes are connected to each other by solder connection using a Cu core solder-plated ball, the adhesion of the substrate consists of a three-layer adhesive material consisting of an adhesive layer, a ball holding core layer, and an adhesive layer, and solder of the Cu core solder-plated ball dropped into holes of the three layers is collectively thermocompression-bonded.

JP2005-161338A describes a solder sheet in which metal spheres having a higher melting point than solder forming a matrix are dispersed, and describes that the metal spheres have an average diameter of 30 to 300 μm and a standard deviation of a diameter distribution of 2.0 μm or less.

JP5585751B1 describes that an electronic component is configured by bonding a solder bump of a semiconductor chip and an electrode of a printed circuit board with a solder paste, and the solder bump is formed by bonding a Cu ball to an electrode of the semiconductor chip.

JP2008-270846A describes that a solder bonding layer is melted by being heated in a state where a filler having a thickness smaller than a thickness of the solder bonding layer before being melted is disposed on the solder bonding layer before being melted, and the solder bonding layer is solidified by being cooled in a state where the filler is dropped into the melted solder bonding layer, thereby making the thickness of the solder bonding layer for bonding a heat sink and an insulating substrate to a desired thickness.

JP2012-028433A describes applying a paste-like coating agent containing a conductive material that is solid at room temperature and melted by being heated and a solvent onto a base material to form a coating agent layer, embedding a plurality of conductive solid spacers that do not change in shape by being heated and that regulate an interval between the base material and an electronic component in the coating agent layer, placing the electronic component on the coating agent layer, and heating the base material while pressing the electronic component against the base material to melt the conductive material in the coating agent layer, and then re-solidifying the conductive material by natural cooling or cooling to bond the electronic component to the base material.

### SUMMARY OF THE INVENTION

### Technical Problem

Although solder is less expensive as the bonding material, the sintering material offers superior performance.

In view of the above issues, an object of the present disclosure is to provide a semiconductor device in which solder bonding of a semiconductor chip is improved.

### Solution to Problem

In order to achieve the above object, an aspect of the present disclosure provides a semiconductor device including: (a) a semiconductor chip including a lower main electrode on a lower side; (b) an insulated circuit board including an insulating substrate and an upper conductor layer disposed on an upper surface of the insulating substrate; and (c) a bonding layer that bonds the lower main electrode of the semiconductor chip to the upper conductor layer, in which (d) the bonding layer includes a solder material containing tin, a filler containing a first metal having a higher melting point than the solder material and disposed in the solder material, and an alloy layer consisting of an alloy of tin contained in the solder material and the first metal and provided on a surface of the filler, and (e) the alloy layer connects the lower main electrode and the upper conductor layer.

Further, the alloy layer may be provided on the surface of the filler with a thickness of 10 μm or more.

Further, a thickness of the filler may be approximately the same as a thickness of the bonding layer.

Further, the filler may be provided at least at each of four corner portions of the semiconductor chip in plan view.

Further, a laser resist region may be provided on an upper surface of the upper conductor layer, and the filler may be disposed on the laser resist region.

Further, the first metal may be a metal capable of forming an alloy with tin, and the melting point of the first metal is 270 °C or higher.

Further, the first metal may be any of tellurium, titanium, thallium, vanadium, yttrium, zinc, zirconium, arsenic, gold, silver, bismuth, cadmium, cobalt, copper, iron, germanium, magnesium, manganese, niobium, nickel, lead, palladium, platinum, and antimony.

Further, the alloy layer may be provided on the surface of the filler with a thickness of 2 μm or more.

The above summary of the invention does not enumerate all the necessary features of the present invention. Sub-combinations of these feature groups may also constitute the invention.

### BRIEF DESCRIPTION OF THE DRAWINGS

FIG. 1 is a schematic longitudinal cross-sectional view illustrating an example of a schematic configuration of a semiconductor device according to a first embodiment of the present disclosure;

FIG. 2 is a schematic longitudinal cross-sectional view illustrating an enlarged schematic configuration of an upper conductor layer, a bonding layer, and the semiconductor chip in FIG. 1;

FIG. 3 is a plan view illustrating an example of a schematic configuration of the bonding layer according to the first embodiment of the present disclosure;

FIG. 4 is a plan view illustrating an example of a schematic configuration of a bonding layer according to a first modification of the first embodiment of the present disclosure;

FIG. 5 is a plan view illustrating an example of a schematic configuration of an upper conductor layer and a laser resist region according to a second modification of the first embodiment of the present disclosure;

FIG. 6 is a plan view illustrating another example of the schematic configuration of the upper conductor layer and the laser resist region according to the second modification of the first embodiment of the present disclosure; and

FIG. 7 is a table showing characteristics of various bonding materials.

### DETAILED DESCRIPTION

Hereinafter, embodiments of the present disclosure will be described with reference to the accompanying drawings. In the description of the drawings, the same or similar parts will be denoted by the same or similar reference numerals and duplicated descriptions will be omitted. However, the drawings are schematic, and a relationship between a thickness and a planar dimension, a ratio between thicknesses of respective layers, and the like may differ from actual ones. In addition, the drawings may include parts having different dimensional relationships or ratios. In addition, the following embodiments describe examples of devices and methods for embodying the technical idea of the present disclosure, and the technical idea of the present disclosure does not specify the material, the shape, the structure, the arrangement, and the like of the components in the following embodiments. Further, the technical idea of the present disclosure may be modified in various manners within the technical scope specified by the claims described in the claims.

In the present specification, a source region of a metal-oxide-semiconductor field-effect transistor (MOSFET) is a “one main region (first main region)” that can be selected as an emitter region of an insulated-gate bipolar transistor (IGBT). In addition, in a thyristor such as a MOS-controlled static induction thyristor (SI thyristor), the “one main region” can be selected as a cathode region. A drain region of the MOSFET is an “other main region (second main region)” of the semiconductor device, which is selectable as a collector region in the IGBT and an anode region in the thyristor. In the present specification, the “main region” simply means any one of the first main region or the second main region, which is appropriate from the technical common knowledge of those skilled in the art.

The definitions of directions such as up, down, and the like in the following description are merely definitions for convenience of description, and do not limit the technical idea of the present disclosure. For example, it goes without saying that, when an object is observed after being rotated by 90°, upper and lower sides are read as right and left sides, and when the object observed after being rotated by 180°, the upper and lower sides are read as inverted. Further, an “upper surface” may be read as a “front surface”, and a “lower surface” may be read as a “back surface”.

### First Embodiment

### Configuration of Semiconductor Device

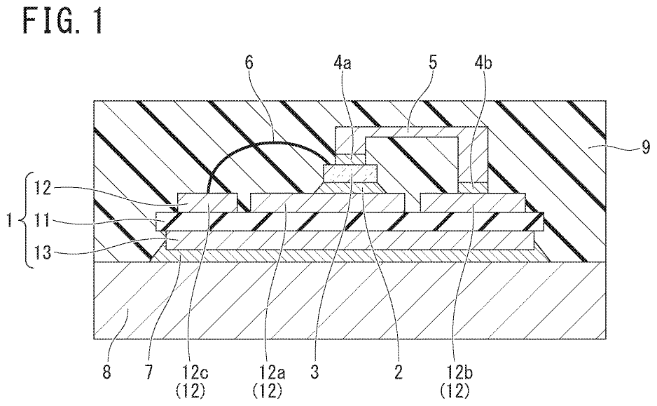

As illustrated in FIG. 1, a semiconductor device according to a first embodiment includes an insulated circuit board 1 and a semiconductor chip 3 mounted on the insulated circuit board 1 via a bonding layer 2. A lower surface of the insulated circuit board 1 is bonded to a cooling plate 8 with solder 7. The periphery of the semiconductor chip 3 is sealed by a sealing member 9, and is electrically insulated from the surroundings. The sealing member 9 is, for example, a gel, but may be a resin such as an epoxy resin.

### Insulated Circuit Board

The insulated circuit board 1 includes an insulating substrate 11, an upper conductor layer 12 disposed on an upper surface of the insulating substrate 11, which is a circuit surface side, and a lower conductor layer 13 disposed on a lower surface of the insulating substrate 11, which is a cooling surface side. The upper conductor layer 12 includes upper conductor layers 12a, 12b, and 12c provided separately from each other. When the upper conductor layers 12a, 12b, and 12c are not distinguished from each other, the upper conductor layers 12a, 12b, and 12c are simply referred to as the upper conductor layer 12. In addition, the number of upper conductor layers 12 provided separately is not limited to FIG. 1.

The insulated circuit board 1 may be, for example, a direct copper bonding (DCB) substrate, an active metal brazing (AMB) substrate, or the like. The insulating substrate 11 is formed of, for example, a ceramic substrate consisting of aluminum oxide (Al₂O₃), aluminum nitride (AlN), silicon nitride (Si₃N₄), or the like, or a resin insulating substrate using a resin material such as a polymer material. The upper conductor layer 12 and the lower conductor layer 13 are formed of, for example, a conductor foil or a conductive plate using a metal material such as copper (Cu) or aluminum (Al). In the present embodiment, a case will be described in which the upper conductor layer 12 and the lower conductor layer 13 are formed of copper.

### Semiconductor Chip

The semiconductor chip 3 differs in type depending on the application, and may be, for example, a power semiconductor element such as an IGBT, a reverse-conducting IGBT (RC-IGBT), a reverse-blocking IGBT (RB-IGBT), a field-effect transistor (FET) such as a MOSFET, a static induction (SI) thyristor, or a gate turn-off (GTO) thyristor, or a rectifying element such as a Schottky barrier diode (SBD). The semiconductor chip 3 may be formed of, for example, a silicon (Si) substrate, or may be formed of a compound semiconductor substrate consisting of a wide band gap semiconductor such as silicon carbide (SiC), gallium nitride (GaN), or gallium oxide (Ga₂O₃). The semiconductor device according to the first embodiment may include one or a plurality of semiconductor chips 3. The semiconductor chip 3 is, for example, a power semiconductor chip.

When the MOSFET is mounted as the semiconductor chip 3, the semiconductor chip 3 has a control electrode (gate electrode) and an upper main electrode (source electrode) on an upper surface side, and has a lower main electrode (drain electrode) on a lower surface side. When the IGBT or the RC-IGBT is mounted as the semiconductor chip 3, the semiconductor chip 3 has a control electrode (gate electrode) and an upper main electrode (emitter electrode) on an upper surface side, and has a lower main electrode (collector electrode) on a lower surface side. When the SI thyristor, the GTO thyristor, or the SBD is mounted as the semiconductor chip 3, the semiconductor chip 3 has an upper main electrode on an upper surface side, and has a lower main electrode on a lower surface side. In the present embodiment, as an example, a case will be described in which the MOSFET is mounted in the semiconductor chip 3.

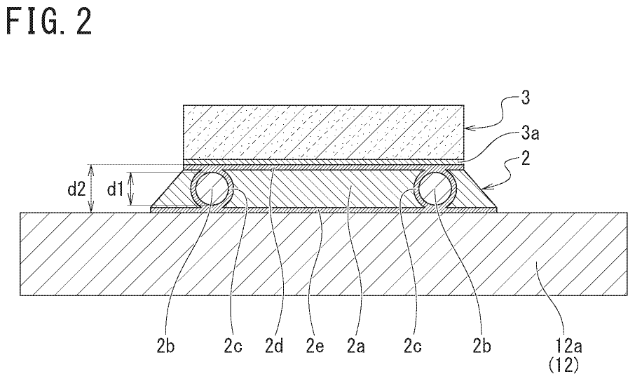

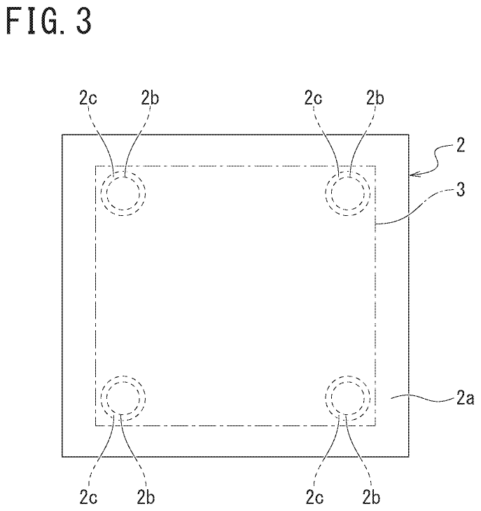

As illustrated in FIG. 3, the semiconductor chip 3 has a rectangular shape in plan view and has four corner portions. As illustrated in FIG. 2, a lower main electrode 3a of the semiconductor chip 3 is bonded to the upper conductor layer 12a with the bonding layer 2. A material forming the lower main electrode 3a is a metal material. In the present embodiment, a case will be described in which the lower main electrode 3a is formed of nickel (Ni) and gold (Au). The lower main electrode 3a is mainly formed of nickel, and a surface thereof is covered with gold. As illustrated in FIG. 1, an upper main electrode (not illustrated) of the semiconductor chip 3 is electrically connected to the upper conductor layer 12b via, for example, a lead frame 5 made of a metal material. More specifically, one end portion of the lead frame 5 is bonded to the upper main electrode with solder 4a, and the other end portion of the lead frame 5 is bonded to the upper conductor layer 12b with solder 4b. The control electrode (not illustrated) of the semiconductor chip 3 is electrically connected to the upper conductor layer 12c via a wire wiring 6 made of a metal material, for example. More specifically, one end portion of the wire wiring 6 is bonded to the control electrode, and the other end portion of the wire wiring 6 is bonded to the upper conductor layer 12c. The solders 4a, 4b, and 7 illustrated in FIG. 1 are bonding materials made of a metal material. As the solder material, for example, a tin-antimony (SnSb)-based material or a tin-silver (SnAg)-based material may be used.

### Bonding layer

As illustrated in FIG. 2, a bonding layer 2 is interposed between the lower main electrode 3a and the upper conductor layer 12a. The bonding layer 2 includes a solder material 2a containing tin (Sn), a filler 2b disposed in the solder material 2a, and an alloy layer 2c provided on a surface of the filler 2b consisting of an alloy of tin contained in the solder material 2a and a metal contained in the filler 2b. The bonding layer 2 further includes an alloy layer 2d provided on a surface of the lower main electrode 3a, and an alloy layer 2e provided on a surface of the upper conductor layer 12a.

The solder material 2a is a bonding material made of a metal material. A main material forming the solder material 2a is, for example, tin, and various materials are added to the tin. As the solder material 2a, for example, a tin-antimony (SnSb)-based material or a tin-silver (SnAg)-based material may be used. In the present embodiment, an example will be described in which Sn-5Sb is used as the solder material 2a. As the solder material forming the solders 4a, 4b, and 7, the same material as the solder material 2a may be used. During the manufacturing of the semiconductor device according to the first embodiment, the solder material 2a is melted when heated. The solder material 2a in a molten state bonds the lower main electrode 3a to the upper conductor layer 12a. Tin contained in the solder material 2a in a molten state forms an alloy layer 2d with the metal material (mainly nickel) forming the lower main electrode 3a and forms an alloy layer 2e with the metal material (mainly copper) forming the upper conductor layer 12a. Thereafter, when solder material 2a is cooled, the solder material 2a is solidified. The solidified solder material 2a extends between the alloy layer 2d and the alloy layer 2e. The alloy layer 2d is formed to cover the lower main electrode 3a, and the alloy layer 2e is formed to cover the upper conductor layer 12a.

As illustrated in FIG. 3, the filler 2b is provided at each of four corner portions of the semiconductor chip 3 in plan view. More specifically, the filler 2b is disposed at a position overlapping the four corner portions of the semiconductor chip 3 in plan view. In FIG. 3, one filler 2b is disposed at one corner portion, but a plurality of fillers 2b may be disposed at one corner portion. In addition, the number of fillers 2b disposed at one corner portion may be the same for all the corner portions or may be different for each corner portion.

As illustrated in FIG. 2, a thickness d1 of the filler 2b is approximately the same as a thickness d2 of the bonding layer 2. “Approximately the same dimension” means that the thickness d1 of the filler 2b is about 90% or more of the thickness d2 of the bonding layer 2 and equal to or less than the thickness d2 of the bonding layer 2 (0.9×d2≤d1≤d2). In order to suppress a large difference in the thickness of the bonding layer 2 at the planar position, it is desirable that the thickness d1 of the filler 2b is as uniform as possible in a plurality of fillers. For example, by sieving the filler 2b in advance, a filler that is too large and a filler that is too small can be removed. For example, by sieving the filler 2b through a plurality of sieves having different mesh sizes, a filler that is too large and a filler that is too small can be removed. The thickness d1 of the filler 2b may be determined in accordance with the target thickness d2 of the bonding layer 2. The thickness d1 of the filler 2b is, for example, about 20 μm or more and 50 μm or less. In addition, for example, when the target thickness d2 of the bonding layer 2 is 50 μm, the filler 2b having a thickness d1 of about 90% or more of 50 μm and 50 μm or less may be used.

In the present embodiment, the shape of the filler 2b is spherical as illustrated in FIGS. 2 and 3. The shape of the filler 2b may be other shapes than the spherical shape, and may be, for example, a scale-like shape or a needle-like shape. The scale-like filler 2b has a scaly shape, a metal-flake shape, or a shape like a flattened sphere, and can be formed, for example, by shaving off a metal material as a raw material or as molten fine powder. The needle-like filler 2b is, for example, a needle-like crystal of a metal. A dimension of the needle-like filler 2b in a longitudinal direction is about equal to or greater than the diameter and equal to or smaller than 110% of the diameter. The filler 2 b having a spherical shape, a scale-like shape, and a needle-like crystal has a smaller contact area with the lower main electrode 3a and the upper conductor layer 12a compared with a flat plate-like metal piece.

The filler 2b includes a metal material capable of forming an alloy with the solder material 2a. More specifically, the filler 2b includes a metal material capable of forming an alloy with tin contained in the solder material 2a. Hereinafter, the metal material capable of forming the alloy with tin will be referred to as a first metal. The filler 2b consists only of the first metal or mainly contains the first metal. The interior of the filler 2b, for example, an inner portion deeper than 10 μm from the surface, may contain no first metal and may consist of an insulator such as ceramic. In addition, as the first metal, a metal material having a higher melting point than the solder material 2a is adopted. For example, the melting point of the solder material 2 a is about 240 °C, and the melting point of the first metal is 270 °C or higher. The first metal is, for example, any of tellurium (Te: 449.5 °C), titanium (Ti: 1668.0 °C), thallium (Tl: 304.0 °C), vanadium (V: 1910.0 °C), yttrium (Y: 1526.0 °C), zinc (Zn: 419.5 °C), zirconium (Zr: 1855.0 °C), arsenic (As: 817.0 °C), gold (Au: 1064.2 °C), silver (Ag: 961.8 °C), bismuth (Bi: 271.5 °C), cadmium (Cd: 321.1 °C), cobalt (Co: 1495.0 °C), copper (Cu: 1084.6 °C), iron (Fe: 1538.0 °C), germanium (Ge: 938.3 °C), magnesium (Mg: 650.0 °C), manganese (Mn: 1246.0 °C), niobium (Nb: 2477.0 °C), nickel (Ni: 1455.0 °C), lead (Pb: 327.5 °C), palladium (Pd: 1554.9 °C), platinum (Pt: 1768.3 °C), and antimony (Sb: 630.6 °C). For some metals of the first metal, the melting point is described together with the substance name. In the present embodiment, the first metal will be described as copper.

Hereinafter, the alloy layer 2c will be described. During the manufacturing of the semiconductor device according to the first embodiment, the solder material 2a is melted when heated. Tin contained in the solder material 2a in a molten state forms the alloy layer 2c with the first metal (copper) contained in the filler 2b. The alloy layer 2c is formed to cover the filler 2b. The alloy layer 2c is a column that connects the lower main electrode 3a and the upper conductor layer 12a along a thickness direction of the bonding layer 2. A bonding portion between the alloy layer 2c and the upper conductor layer 12a may include both the alloy layer 2c and the alloy layer 2e. A bonding portion between the alloy layer 2c and the lower main electrode 3a may include both the alloy layer 2c and the alloy layer 2d. The alloy layer 2c is provided on the surface of the filler 2b with a thickness of, for example, about 10 μm or more and 15 μm or less. The alloy layer 2d is provided on the surface of the lower main electrode 3a with a thickness of, for example, about 1 μm. The alloy layer 2e is provided on the surface of the upper conductor layer 12a with a thickness of, for example, about 2 μm. Although the filler 2b and the upper conductor layer 12a are made of copper, the filler 2b is not subjected to a high-temperature heat treatment unlike the upper conductor layer 12a, so that the thickness of the alloy layer 2c is greater than the thickness of the alloy layer 2e. The greater the thickness of the alloy layer 2c, the higher the connection strength for connecting the lower main electrode 3a and the upper conductor layer 12a. The connection strength between the lower main electrode 3a and the upper conductor layer 12a can be further increased by providing the alloy layer 2c as a thick film having a thickness of 10 μm or more. Since the connection strength between the lower main electrode 3a and the upper conductor layer 12a can be increased merely by the presence of the alloy layer 2c, the thickness of the alloy layer 2c may be less than 10 μm. The thickness of the alloy layer 2c may be, for example, a thickness of 2 μm or more. Further, the thickness of the alloy layer 2c may be, for example, a thin film of 2 μm or more and less than 10 μm.

Since the melting point and strength of the first metal are higher than the melting point and the strength of the solder material 2a, the melting point and strength of the alloy layer 2c are also higher than the melting point and the strength of the solder material 2a. The melting points and strengths of the alloy layers 2d and 2e are also higher than the melting point and strength of the solder material 2a. Since the alloy layer 2c is formed on the surface of the filler 2b, the planar position at which the alloy layer 2c is provided can be controlled by controlling the planar position at which the filler 2b is disposed. In the present embodiment, by providing the filler 2b at each of the four corner portions of the semiconductor chip 3 in plan view, the alloy layer 2c can be provided at each of the four corner portions of the semiconductor chip 3 in plan view.

### Manufacturing Method of Semiconductor Device

Hereinafter, a manufacturing method of the semiconductor device according to the first embodiment will be described. In the present embodiment, the bonding of the semiconductor chip 3 to the upper conductor layer 12a of the insulated circuit board 1 will be described, and solder bonding other than that and manufacturing step other than that will not be described.

First, a paste-like solder material is applied to a region of an upper surface of the upper conductor layer 12a where the semiconductor chip 3 is mounted. The solder material is applied using, for example, a squeegee. The particle diameter of the particles contained in the paste-like solder material is a particle diameter equal to or less than the target thickness of the bonding layer 2. The particle diameter of the particles is, for example, about 15 μm or less. Next, the filler 2b is disposed on the upper surface of the applied paste-like solder material using, for example, a mounter. The filler 2b is mixed in advance with a liquid flux, and is applied together with the liquid flux to four corner portions of the paste-like solder material. The amount of filler 2b disposed at one location is about 1/2000 or more and 1/1000 or less in terms of % by weight (wt %) with respect to the paste-like solder material. The number of the fillers 2b disposed at one location is one or a plurality. The semiconductor chip 3 is disposed on the paste-like solder material and the filler 2b. When the semiconductor chip 3 is disposed, the filler 2b is pressed by the semiconductor chip 3, and sinks into the paste-like solder material. The filler 2b having a shape in which the contact area with the lower main electrode 3a and the upper conductor layer 12a is small is more likely to sink into the paste-like solder material compared with a flat plate-shaped metal piece. The solder material is heated in a nitrogen furnace or a formic acid furnace. A heating temperature is, for example, about 270 °C, and a heating time is about 3 minutes at a peak temperature. By melting the solder material, the semiconductor chip 3 is bonded to the upper conductor layer 12a, and the alloy layers 2c, 2d, and 2e are formed. Then, the solder material is cooled and solidified to obtain the solder material 2a.

### Main Effect of First Embodiment

According to the semiconductor device of the first embodiment, the bonding layer 2 that bonds the lower main electrode 3a of the semiconductor chip 3 to the upper conductor layer 12a includes the solder material 2a containing tin and the filler 2b containing the first metal having a higher melting point than the solder material 2a and disposed in the solder material 2a. Therefore, the filler 2b functions as a spacer, and the thickness of the bonding layer 2 can be formed to be approximately the same as that of the filler 2b. As a result, the thickness of the bonding layer 2 can be reduced, and the thermal resistance and electrical resistance of the bonding layer 2 can be reduced. Further, the melting point and strength of the alloy layer 2c are higher than the melting point and strength of the solder material 2a. Therefore, it is possible to suppress the decrease in reliability even when the thickness of the bonding layer 2 is set to be thin. In addition, since the alloy layer 2c having higher melting point and strength than the solder material 2a connects the lower main electrode 3a and the upper conductor layer 12a, the bonding strength between the semiconductor chip 3 and the insulated circuit board can be increased.

In addition, according to the semiconductor device of the first embodiment, the alloy layer 2c is provided on the surface of the filler 2b with a thickness of 2 μm. Therefore, it is possible to suppress the decrease in reliability even when the thickness of the bonding layer 2 is set to be thin. In addition, according to the semiconductor device of the first embodiment, the alloy layer 2c is provided on the surface of the filler 2b with a thickness of 10 μm or more. By providing the alloy layer 2c with a thick film, it is possible to further suppress the decrease in reliability even when the thickness of the bonding layer 2 is set to be thin.

In addition, according to the semiconductor device of the first embodiment, the filler 2b and the alloy layer 2c are provided at each of the four corner portions of the semiconductor chip 3 in plan view. Therefore, the strength of the bonding layer 2 located in the vicinity of the four corner portions of the semiconductor chip 3 can be increased. As a result, cracks are less likely to occur in the corner portions of the bonding layer 2. In addition, since the filler 2b is disposed at a plurality of positions, it is possible to suppress a significant non-uniformity in the thickness of the bonding layer 2.

### First Modification of First Embodiment

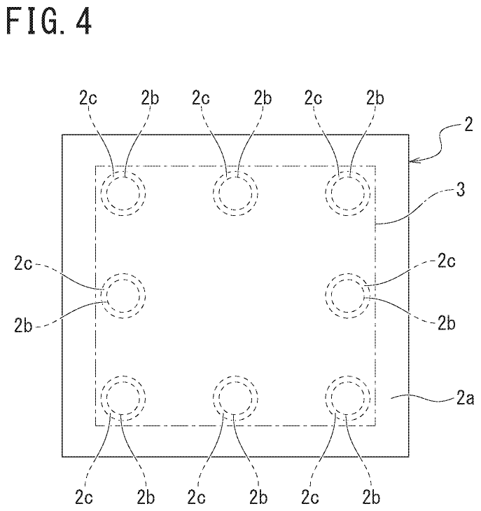

A semiconductor device according to a first modification of the first embodiment is different from the semiconductor device according to the first embodiment illustrated in FIG. 3 in that the filler 2b is provided not only at the four corner portions of the semiconductor chip 3 in plan view but also at an outer peripheral portion of the semiconductor chip 3 in plan view, as illustrated in FIG. 4. The other configurations of the semiconductor device according to the first modification of the first embodiment are the same as those of the semiconductor device according to the first embodiment, and thus the duplicated description will be omitted.

By disposing the filler 2b and the alloy layer 2c in a portion in which the cracks are likely to occur in the bonding layer 2, it is possible to reinforce the portion in which the cracks are likely to occur in the bonding layer 2. The cracks may occur not only in the corner portions of the bonding layer 2 but also in the outer peripheral portion of the bonding layer 2. Therefore, the filler 2b is also disposed at a position overlapping the outer peripheral portion of the semiconductor chip 3 in plan view. The filler 2b may be disposed at a plurality of positions along the outer peripheral portion of the semiconductor chip 3. Therefore, the alloy layer 2c can also be provided in the outer peripheral portion of the bonding layer 2.

According to the semiconductor device of the first modification of the first embodiment, since the filler 2b is provided in the vicinity of both the four corner portions and the outer peripheral portion of the semiconductor chip 3, it is possible to further suppress the decrease in reliability even when the thickness of the bonding layer 2 is set to be thin. In addition, the bonding strength between the semiconductor chip 3 and the insulating circuit board can be further increased.

### Second Modification of First Embodiment

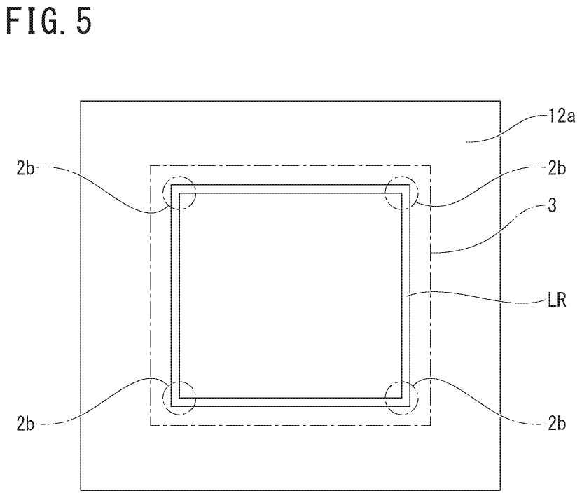

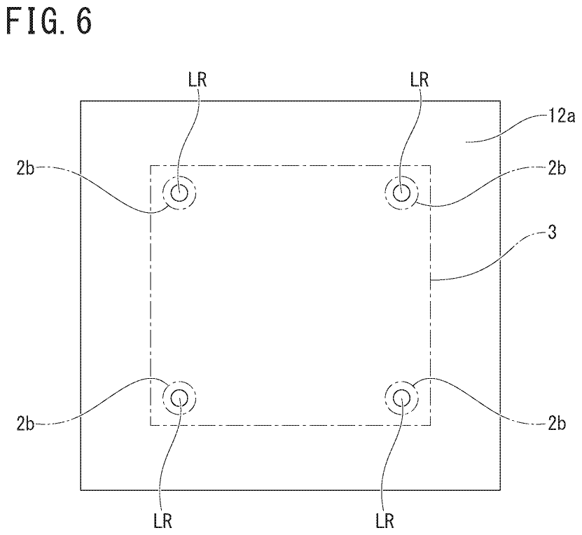

A semiconductor device according to a second modification of the first embodiment is different from the semiconductor device according to the first embodiment illustrated in FIG. 3 in that a laser resist region LR is provided on the upper surface of the upper conductor layer 12a, as illustrated in FIGS. 5 and 6. The other configurations of the semiconductor device according to the second modification of the first embodiment are the same as those of the semiconductor device according to the first embodiment, and thus the duplicated description will be omitted.

The laser resist region LR is provided on the upper surface of the upper conductor layer 12a before the solder material is applied. The laser resist region LR is formed by irradiating the upper surface of the upper conductor layer 12a with laser light. When the upper surface of the upper conductor layer 12a is irradiated with laser light, unevenness is generated on the upper surface. In addition, the laser resist region LR may be a groove formed to be recessed relative to the upper surface of the upper conductor layer 12a other than the laser resist region LR. As the form of the laser resist region LR, an oxide film may be formed. The filler 2b is disposed on the laser resist region LR. By providing the laser resist region LR on the upper surface of the upper conductor layer 12a, when the solder material 2a is heated and melted during the manufacturing, the filler 2b disposed on the laser resist region LR is less likely to move. During the manufacturing, when the filler 2b is disposed on the upper surface of the paste-like solder material, the laser resist region LR is covered with the paste-like solder material. However, by identifying the position of the laser resist region LR based on the coordinates, the filler 2b can be disposed above the laser resist region LR.

As illustrated in FIG. 5, the laser resist region LR may be a straight line in plan view. More specifically, the laser resist region LR may have a rectangular annular shape in plan view. In addition, as illustrated in FIG. 6, the laser resist region LR may be provided in a spot shape at a position at which the filler 2b is disposed.

According to the semiconductor device of the second modification of the first embodiment, since the laser resist region LR is provided on the upper surface of the upper conductor layer 12a, it is possible to suppress the large positional deviation of the filler 2b during the manufacturing. As a result, it is possible to suppress a large positional deviation of the filler 2b from a portion in which the cracks are likely to occur in the bonding layer 2, and it is possible to accurately reinforce the portion in which the cracks are likely to occur in the bonding layer 2.

### Overview

A power semiconductor is a semiconductor device capable of carrying a large current at a high voltage, handling a direct current voltage and an alternating current voltage, and converting the direct current voltage and the alternating current voltage to each other. The power semiconductor can change a voltage and a frequency of the alternating current voltage, and is widely used for rotation control of a motor. A general power semiconductor device includes, for example, a semiconductor chip including a semiconductor element such as an IGBT or a MOSFET, a printed circuit board (PCB), an insulated circuit board, a heat dissipation base, and the like. A solder material, a sintering material, or the like is used for bonding between the semiconductor chip, the insulated circuit board, and the heat dissipation base. In recent years, in power semiconductor devices, higher circuit integration has been advancing due to demands for higher functionality as well as reductions in size and weight. Further, development is underway for application to semiconductor devices using semiconductor elements such as silicon carbide (SiC) capable of high-temperature operation, and high reliability of the semiconductor devices is required under high-temperature operating environments.

A solder material such as a tin-antimony (SnSb)-based material or a tin-silver (SnAg)-based material has been widely used as a bonding material of the semiconductor device. However, as the operating temperature of the semiconductor device approaches the melting point of the solder material, the decrease in reliability is a concern. Accordingly, as a bonding material capable of supporting high-temperature operation, a sintered metal layer utilizing a sintering action of metal particles such as silver (Ag) or copper (Cu) has come to be applied.

The power semiconductor device incorporates a circuit that handles a large current, and locally generates heat due to high resistance or low heat transfer in wiring connection of the circuit. In a power semiconductor device using silicon carbide (SiC) or the like, the current flowing inside increases, and thus it is important, as an electric circuit, to suppress heat generation (internal loss) to a low level. However, with solder bonding methods in the related art, it is necessary to increase the thickness of the solder bonding layer to ensure reliability, making it increasingly difficult to suppress reductions in thermal conduction and electrical conduction.

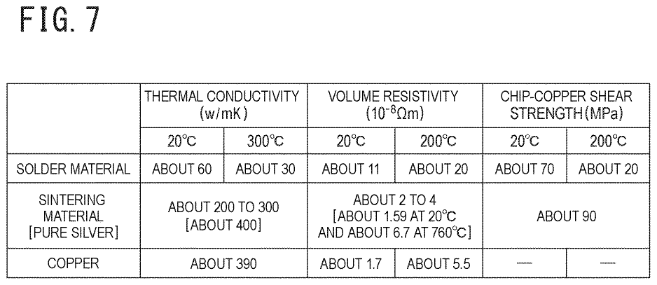

There are two types of pre-bonding forms of the sintering material, that is, paste-like and sheet-like materials, and in any case, in order to obtain a high-strength sintering material bond, it is necessary to pressurize the bonding portion (20 MPa or more) and simultaneously heat the bonding portion (250 °C or higher). Therefore, during bonding, a plurality of semiconductor chips are placed on the sintering material disposed on an insulating substrate, and the sintering material is sintered by heating while simultaneously applying pressure to the upper surfaces of the chips. As shown in FIG. 7, the electrical resistance and thermal resistance of the solder material are one order of magnitude higher (and the thermal conductivity is one order of magnitude lower) than the electrical resistance and thermal resistance of the sintering material and the copper material, and when the temperature is raised to 200 °C, the volume resistivity further increases. There, the solder bonding portion serves as a heat generation source and also as a thermal resistance to heat dissipation from the chip, causing a temperature rise. The bonding material also requires bonding strength in a high temperature state, and the strength of the solder bonded product decreases at a high temperature.

However, in a cost comparison, the cost of the solder material is about one hundredth of the cost of the sintering material, and the price of the bonding apparatus can also be kept low to about one tenth. Therefore, the cost advantage of using the solder material is high.

Although the strength increases when the solder bonding layer is made into an alloy with the first metal, converting the entire layer into an alloy layer requires a long heating time, resulting in an extremely difficult manufacturing method. In current solder bonding, a solder alloy layer is formed on a chip surface electrode or on a surface of a member to be bonded with a thickness of several micrometers. When another member to be bonded is added into the solder layer and brought into contact between the chip and the member to be bonded, an alloy layer is formed with the added member as a nucleus, making it possible to connect the chip and the member to be bonded with the alloy layer. Since the solder alloy layer has high mechanical strength, high reliability can be obtained even when the solder bonding layer is set to be thin. Further, when the solder bonding layer is set to be thin, the electrical resistance and thermal conductivity can be suppressed to be low.

### Other Embodiments

The first embodiment and the modifications thereof have been described, but the description and drawings forming part of the present disclosure should not be understood as limiting the present disclosure. From the present disclosure, various alternative embodiments, examples, and operational technologies will be apparent to those skilled in the art.

In addition, the configurations disclosed in the first embodiment and the modifications thereof can be combined as appropriate within a range in which no contradictions occur. For example, the filler 2b illustrated in FIG. 4 and the laser resist region LR illustrated in FIGS. 5 and 6 may be combined. Accordingly, it goes without saying that the present disclosure includes various embodiments and the like that are not described herein. Accordingly, the technical scope of the present disclosure is defined only by the matters specifying the invention according to claims that are appropriate based on the above description.

1. A semiconductor device comprising:
a semiconductor chip including a lower main electrode on a lower side;
an insulated circuit board including an insulating substrate and an upper conductor layer disposed on an upper surface of the insulating substrate; and
a bonding layer that bonds the lower main electrode of the semiconductor chip to the upper conductor layer,
wherein the bonding layer includes a solder material containing tin, a filler containing a first metal having a higher melting point than the solder material and disposed in the solder material, and an alloy layer consisting of an alloy of tin contained in the solder material and the first metal and provided on a surface of the filler, and
the alloy layer connects the lower main electrode and the upper conductor layer.

2. The semiconductor device according to claim 1,
wherein the alloy layer is provided on the surface of the filler with a thickness of 10 μm or more.

3. The semiconductor device according to claim 1,
wherein a thickness of the filler is approximately the same as a thickness of the bonding layer.

4. The semiconductor device according to claim 1,
wherein the filler is provided at least at each of four corner portions of the semiconductor chip in plan view.

5. The semiconductor device according to claim 4,
wherein a laser resist region is provided on an upper surface of the upper conductor layer, and
the filler is disposed on the laser resist region.

6. The semiconductor device according to claim 1,
wherein the first metal is a metal capable of forming an alloy with tin, and the melting point of the first metal is 270 °C or higher.

7. The semiconductor device according to claim 6,
wherein the first metal is any of tellurium, titanium, thallium, vanadium, yttrium, zinc, zirconium, arsenic, gold, silver, bismuth, cadmium, cobalt, copper, iron, germanium, magnesium, manganese, niobium, nickel, lead, palladium, platinum, and antimony.

8. The semiconductor device according to claim 1,
wherein the alloy layer is provided on the surface of the filler with a thickness of 2 μm or more.
